(19) United States
(12) Patent Application Publication
(10) Pub. No.: US 2026/0040865 A1
(43) Pub. Date: Feb. 5, 2026

(54) HIGH-PRESSURE ANNEALING DEVICE

(71) Applicant: YEST Co., Ltd., Pyeongtaek-si (KR)

(72) Inventors: Young Joon HAM, Pyeongtaek-si (KR); Jeong Eui KIM, Incheon (KR); Yong Hwan KWON, Yongin-si (KR); Jin Seok LEE, Pyeongtaek-si (KR); Byung Wook HWANG, Anseong-si (KR); Yeon Min MO, Pyeongtaek-si (KR); Eun Chan LEE, Yongin-si (KR); Ryun Hwi KIM, Pyeongtaek-si (KR)

(73) Assignee: YEST Co., Ltd., Pyeongtaek-si (KR)

(21) Appl. No.: 19/241,335

(22) Filed: Jun. 17, 2025

(30) Foreign Application Priority Data
Jun. 20, 2024 (KR) 10-2024-0080337

(51) Int. Cl. H01L 21/67; F27B 5/04; F27B 5/16; F27D 7/06

(52) U.S. Cl. CPC H01L 21/67109; F27B 5/04; F27B 5/16; F27D 7/06; F27B 2005/162; F27D 2007/063

(57) ABSTRACT

Disclosed is a high-pressure annealing device including a nozzle assembly. The high-pressure annealing device is configured to prevent, when gas is supplied to the inside of a chamber of the high-pressure annealing device through a gas nozzle, damage generated during coupling of the gas nozzle to a gas supply module.

### CROSS-REFERENCE TO THE RELATED APPLICATION

The present application claims priority to and the benefit of Korean Patent Application No. 10-2024-0080337, filed on Jun. 20, 2024, in the Korean Intellectual Property Office, the entire disclosure of which is herein incorporated by reference.

### BACKGROUND

### 1. Field

The present disclosure relates to a high-pressure annealing device, and more particularly, to a high-pressure annealing device configured to separate an integrated nozzle into a gas nozzle and a gas supply module and to support the gas nozzle using a nozzle support member, thereby preventing damage to the gas nozzle.

### 2. Description of the Related Art

Recently, a high-pressure hydrogen annealing process of removing semiconductor surface defects using high-pressure hydrogen or deuterium has been adopted.

Meanwhile, in order to supply gas into a high-pressure annealing device, a method of inserting an integrated gas nozzle made of quartz into a manifold has been adopted. However, the integrated gas nozzle has a drawback in that a bent portion of the integrated gas nozzle is vulnerable to damage during a maintenance procedure.

In order to address the above-described problem, various techniques have been proposed to prevent damage to the integrated gas nozzle. For example, the integrated gas nozzle is separated into a gas nozzle and a gas supply part connected to a manifold.

However, the existing method of inserting the gas nozzle into one end of the gas supply part causes an inclination of the gas nozzle. Accordingly, gas may not be evenly distributed over a substrate. Additionally, vibration may occur at a coupling location between the gas nozzle and the gas supply part through which high-temperature and high-pressure gas is supplied, and particles may be dropped onto the substrate.

Although the method of inserting the gas nozzle into the gas supply part has been mainly adopted, unlike the integrated gas nozzle, such a method causes damage to the gas nozzle in the process of attaching or detaching the gas nozzle to or from the gas supply part.

In addition, a method of fixing a gas supply module by connecting a support to the lower end of the gas supply part has been mainly adopted, but this method does not solve problems related to inclination and vibration of the gas nozzle.

Therefore, there is demand for a technique capable of not only eliminating damage to a gas nozzle generated when the gas nozzle is inserted into a gas supply part, but also securing vertical alignment of the inserted gas nozzle to reduce vibration of the gas nozzle.

### SUMMARY

Therefore, the present disclosure has been made in view of the above problems, and it is an object of the present disclosure to provide a method of reducing the risk of damage to a gas nozzle during the operation of a high-pressure annealing device.

It is another object of the present disclosure to solve a problem related to damage to a bent portion of an integrated gas nozzle made of quartz during a maintenance procedure of a high-pressure annealing device.

It is a still further object of the present disclosure to solve a problem related to damage generated when a gas nozzle is attached to or detached from a gas supply part in a structural configuration in which the gas nozzle and the gas supply part are separately provided, and to solve a problem related to vibration and particles of the gas nozzle by securing vertical alignment of the gas nozzle.

The objects of the present disclosure are not limited to the above-mentioned objects, and other technical objects not mentioned herein will be clearly understood by those skilled in the art to which the present disclosure pertains from the detailed description of the embodiments.

In accordance with an aspect of the present disclosure, the above and other objects can be accomplished by the provision of a high-pressure annealing device including a chamber having a process space provided therein, the process space being configured for gas supplied thereinto and a substrate to react with each other therein, a nozzle assembly configured to inject the gas into the process space in the chamber, and a chamber support configured to support the chamber mounted thereon, the chamber support including a mounting part formed to protrude from an internal surface thereof, the mounting part being configured for mounting of at least a part of the nozzle assembly thereon, wherein the nozzle assembly includes a gas supply module configured for a lower end of a gas nozzle to be mounted therein, the gas supply module being configured to supply the gas to the gas nozzle, the gas nozzle configured to inject the gas into the process space in the chamber, a nozzle support member including a first support and a second support, the first support being configured to surround and contact a part of one side surface of the gas nozzle, the second support facing the first support and being configured to surround and contact a part of the other side surface of the gas nozzle, the nozzle support member being configured to support the gas nozzle mounted in the gas supply module through coupling between the first support and the second support, and a coupling member configured to couple the first support and the second support to each other.

The chamber support may include a gas supply module insertion hole configured for the gas supply module to be inserted thereinto, the mounting part may be located above the gas supply module insertion hole, the first support may be mounted on an upper end of the mounting part, and a mounting position of the gas nozzle in the gas supply module may be adjusted by moving the part of the one side surface of the gas nozzle toward the internal surface for close contact therebetween.

The first support and the second support may surround a part of the gas nozzle in a state in which both ends of the first support and both ends of the second support correspond to each other and contact each other, and the coupling member may contact and press external surfaces of the first support and the second support to fix the gas nozzle.

The first support may include a flange extending outwards from a lower portion of the first support and a slot located in the flange, the slot having a major axis oriented toward a center of the chamber support from the gas supply module insertion hole, the mounting part may include a hole formed therein corresponding to the slot and configured for a fastener to pass therethrough, and a mounting position of the nozzle assembly may be adjusted by changing a position of the fastener passing through the slot.

The gas supply module may include a supply module body including a nozzle mounting part and a horizontal insertion part, the nozzle mounting part being formed on one side of the supply module body and being configured for the gas nozzle to be mounted therein, the horizontal insertion part being formed on the other side of the supply module body and being inserted into the gas supply module insertion hole, and the nozzle mounting part may include a vertical inlet formed in the nozzle mounting part and configured to introduce the gas into the gas nozzle and a mounting groove formed in an upper end of the nozzle mounting part and configured for the lower end of the gas nozzle to be mounted therein.

The coupling member may include a clip configured to surround an external surface of the first support and an external surface of the second support, the clip being configured to elastically press the respective external surfaces of the first and second supports so as to couple the first support and the second support to each other.

The coupling member may include a clamp configured to surround an external surface of the first support and an external surface of the second support, and a bolt coupled to the clamp so as to allow the first support and the second support to be in close contact with the gas nozzle.

Each of the first support and the second support may include extension parts formed to be respectively bent and extend outwards from both ends of each of the first support and the second support, and fastening holes respectively formed in the extension parts of each of the first support and the second support, wherein the fastening holes in the first support and the fastening holes in the second support are formed to correspond to each other, and the coupling member may include fasteners configured to pass through the respective fastening holes so as to couple the first support to the second support such that the first support and the second support are in close contact with the gas nozzle.

The coupling member may include a slider having a through-hole formed therein and configured for the first support and the second support in contact with each other to be inserted thereinto, and the slider may contact external surfaces of the first support and the second support inserted into the through-hole such that the first support and the second support are in close contact with the gas nozzle.

Each of the first support and the second support may have a first screw thread formed on the external surface thereof, the slider may have a second screw thread formed on an internal surface thereof, and the first screw thread and the second screw thread may be fastened.

The mounting groove may include a nozzle alignment protrusion formed to protrude upwards from a part of the mounting groove, the gas nozzle may include a nozzle alignment groove formed to be recessed inwards at a position corresponding to the nozzle alignment protrusion, and the nozzle alignment protrusion may be aligned with and coupled to the nozzle alignment groove so as to align a direction of an injection port of the gas nozzle.

### BRIEF DESCRIPTION OF THE DRAWINGS

The accompanying drawings, which are incorporated in this specification, illustrate exemplary embodiments and serve to further illustrate the technical ideas of the disclosure in conjunction with the detailed description of exemplary embodiments that follows, and the disclosure is not to be construed as limited to what is shown in such drawings. In the drawings:

FIG. 1 is a cross-sectional view and an enlarged cross-sectional view of a high-pressure annealing device according to an embodiment of the present disclosure;

FIG. 2 is a perspective view of an embodiment of a nozzle assembly applied to the high-pressure annealing device according to the present disclosure;

FIG. 3 is an exploded view of the embodiment of the nozzle assembly applied to the high-pressure annealing device according to the present disclosure;

FIG. 4A and 4B are exploded views of an embodiment of a nozzle support member and a coupling member according to the present disclosure;

FIG. 5A is a cross-sectional view of the nozzle support member and the coupling member shown in FIG. 4, and FIG. 5B is a perspective view of the nozzle support member and the coupling member shown in FIG. 4;

FIGS. 6A and 6B are views showing an embodiment in which a gas nozzle is mounted in a supply module body according to the present disclosure;

FIG. 7 is a view showing another embodiment according to a modification of the supply module body shown in FIGS. 6A and 6B;

FIG. 8 is a view showing an example of adjusting the mounting position of the nozzle assembly applied to the high-pressure annealing device according to the present disclosure;

FIGS. 9A, 9B, and 9C, 10A, 10B, and 10C, 11A, 11B, and 11C, 12A and 12B, and 13A and 13B are views each showing an embodiment according to a modification of the nozzle assembly applied to the high-pressure annealing device according to the present disclosure; and

FIGS. 14A and 14B are views showing an embodiment according to a modification of a gas nozzle and a nozzle mounting part applied to the high-pressure annealing device according to the present disclosure.

### DETAILED DESCRIPTION OF EXEMPLARY EMBODIMENTS

Hereinafter, embodiments of the present disclosure will be described in detail with reference to the accompanying drawings in order to describe the present disclosure, the operational advantages thereof, and the purpose achieved by implementation of the present disclosure.

First, in the present disclosure, the terms used herein are only used to describe specific embodiments and are not intended to limit the present disclosure. In this specification, an expression in a singular form also includes the plural sense, unless clearly specified otherwise in context. Additionally, it should be understood that expressions such as “comprise” and “have” in this specification are intended to designate the presence of indicated features, numbers, steps, operations, components, parts, or combinations thereof, but do not exclude the presence or addition of one or more features, numbers, steps, operations, components, parts, or combinations thereof.

In describing the embodiments disclosed herein, when it is determined that a detailed description of related publicly known techniques may obscure the gist of the embodiments disclosed in this specification, the detailed description thereof will be omitted.

The present disclosure proposes a technique capable of not only preventing damage to a gas nozzle generated when the gas nozzle is inserted into a gas supply module in a nozzle assembly applied to a high-pressure annealing device, but also stably supplying gas by fixing the gas nozzle in the vertical direction and reducing vibration of the gas nozzle.

Hereinafter, the present disclosure will be described with reference to embodiments of the present disclosure.

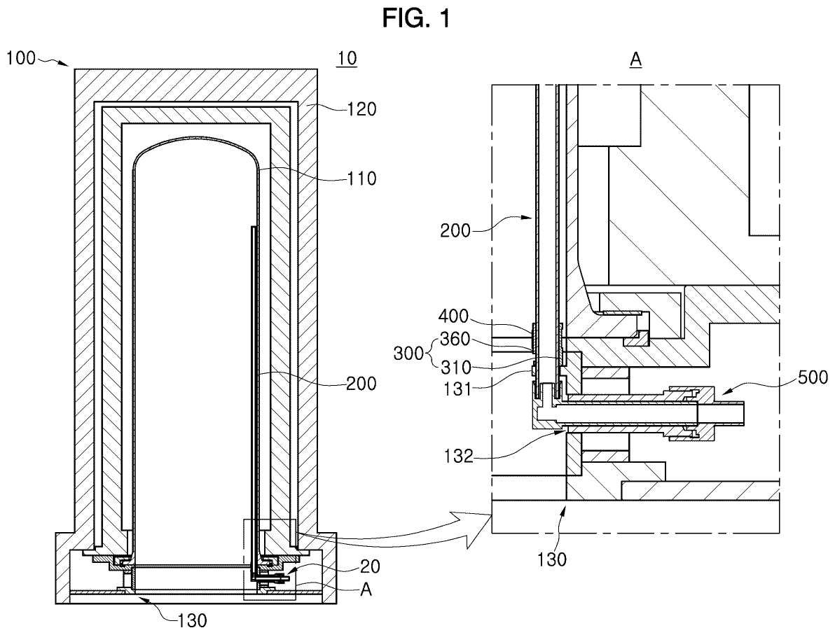

FIG. 1 is a view showing a high-pressure annealing device including a nozzle assembly according to an embodiment of the present disclosure. A high-pressure annealing device 10 to which the present disclosure is applied may be formed of a nozzle assembly 20 and a chamber 100. The chamber 100 may have a dual chamber structure including an external chamber 120 and an internal chamber 110.

The external chamber 120 may be provided to surround the internal chamber 110 in a state of being spaced apart from the internal chamber 110 by a predetermined distance. The external chamber 120 may have an external space provided therein and configured to accommodate the internal chamber 110 and may protect the internal chamber 110 by maintaining the external space at a pressure corresponding to a high pressure of the internal chamber 110. More specifically, the external space may be a space excluding an area occupied by the internal chamber 110 from the internal space provided in the external chamber 120.

The external chamber 120 may be formed of a metallic material, and the material of the external chamber 120 may be appropriately changed depending on circumstances.

The internal chamber 110 may perform an annealing process in a high-pressure environment. As an example, the internal chamber 110 may be formed of a non-metallic material and is preferably formed of quartz. The material of the internal chamber 110 may be appropriately changed depending on circumstances.

The internal chamber 110 may provide a process space in which a heat treatment process is performed on an object to be processed. A door (not shown) may be selectively attached to a lower portion of the internal chamber 110, and the internal space of the internal chamber 110 may be sealed by attachment of the door.

The object to be processed may be positioned in the process space of the internal chamber 110. For example, the object to be processed may be loaded in multiple layers on a wafer boat (not shown) as a wafer and may be positioned in the process space of the internal chamber 110.

Gas supplied to the process space in the internal chamber 110 is a first gas, which is a heat treatment process gas, and may be selected from various heat treatment gases such as hydrogen, deuterium, ammonia, oxygen, chlorine, and nitrogen.

The first gas may be supplied to the process space in the internal chamber 110 through the nozzle assembly 20.

As an example, a gas nozzle 200 of the nozzle assembly 20 may be disposed lengthwise from the lower portion to the upper portion of the process space in the internal chamber 110 so as to supply the first gas to the process space.

A plurality of nozzle assemblies 20 may be arranged, as necessary.

A protective gas may be supplied to control the pressure of the external space of the external chamber 120 at a pressure corresponding to the pressure of the internal chamber 110. A second gas serving as the protective gas supplied to the external space of the external chamber 120 may be selected from various inert gases such as nitrogen.

A gas supply means (not shown) may include a flow meter (not shown) and a pump (not shown) for each of the first gas and the second gas, and a controller may control the gas supply means to follow a heat treatment process profile, thereby adjusting the gas supply amount, the gas supply time, the gas supply speed, the gas supply pressure, and the like for each of the first gas provided to the internal chamber 110 and the second gas provided to the external chamber 120.

A chamber support 130 may support the internal chamber 110.

A sealing member (not shown) capable of preventing gas leakage may be mounted between the chamber support 130 and the internal chamber 110.

An enlarged cross-sectional view A of FIG. 1 is an enlarged view of a part of a longitudinal section of the annealing device and the gas assembly.

As an example, the chamber support 130 has one or more protruding mounting parts 131 on the internal wall surface thereof and one or more gas supply module insertion holes 132 in the internal wall surface thereof, so that the nozzle assembly 20 may be easily mounted on the chamber support 130.

That is, at least one point of the nozzle assembly 20 is mounted on the mounting part 131, and a part of the nozzle assembly 20 is inserted into the gas supply module insertion hole 132, thereby fixing the position of the nozzle assembly 20.

As an example, the chamber support 130 may be a manifold capable of having a plurality of nozzle assemblies 20 mounted thereon, and the manifold may be formed of a metallic material and may be appropriately changed depending on circumferences.

As an example, the chamber support 130 may be provided with a plurality of mounting parts 131 and a plurality of gas supply module insertion holes 132 for mounting of a plurality of nozzle assemblies 20 thereon.

The nozzle assembly 20 may include the gas nozzle 200, a nozzle support member 300, a coupling member 400, and a gas supply module 500.

The gas nozzle 200 may inject gas into the process space.

The nozzle support member 300 may include a first support 310 and a second support 360 each configured to support and align the gas nozzle 200 in the vertical direction and to fix the position of the gas nozzle 200.

The coupling member 400 may allow the first support 310 and the second support 360 of the nozzle support member 300 to be in close contact with the gas nozzle for coupling therebetween.

The gas nozzle 200 may be mounted in the upper end of one side of the gas supply module 500.

The other side of the gas supply module 500 may be inserted into the gas supply module insertion hole 132 located in the internal wall surface of the chamber support 130.

The gas supply module 500 may supply gas introduced from the outside of the chamber 100 to the gas nozzle 200.

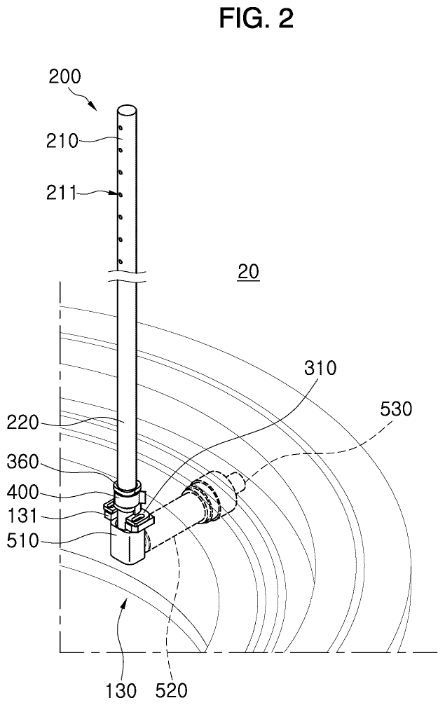

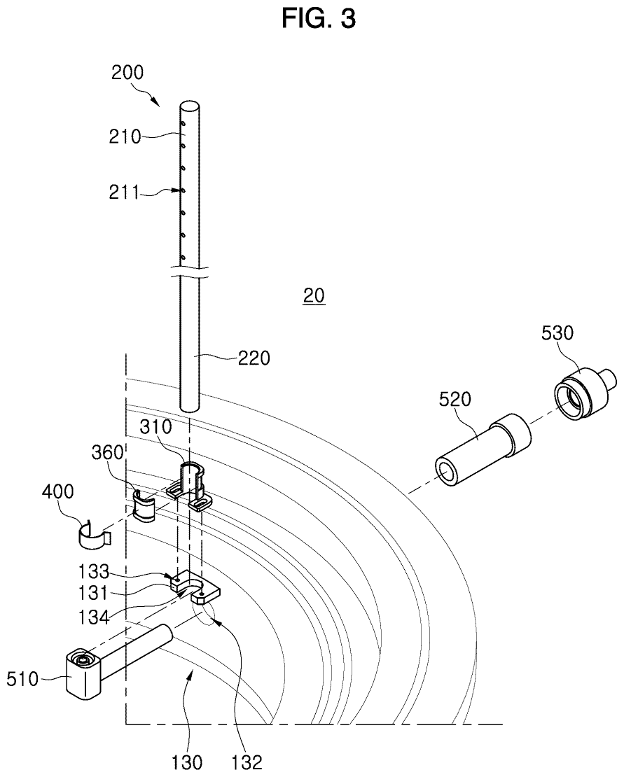

FIG. 2 is a perspective view of an embodiment of the nozzle assembly 20 applied to the high-pressure annealing device 10 according to the present disclosure, and FIG. 3 is an exploded view of the nozzle assembly 20.

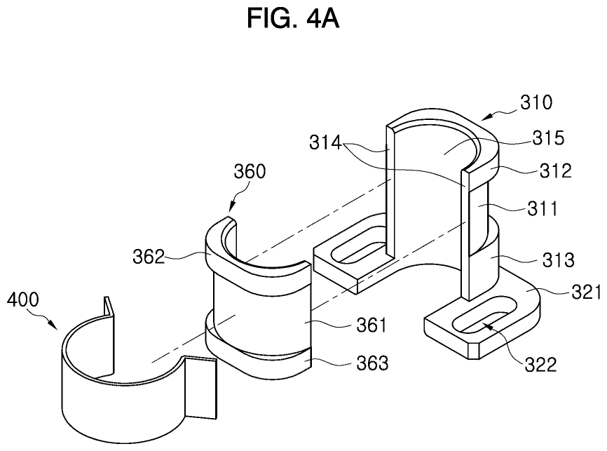

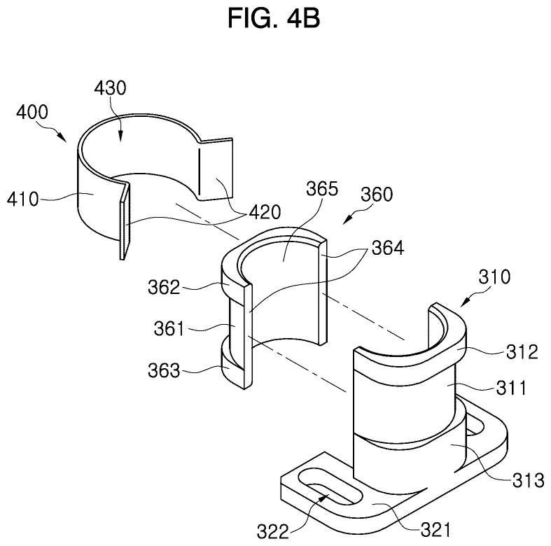

Each component of the present disclosure will be described with reference to FIGS. 4 to 6.

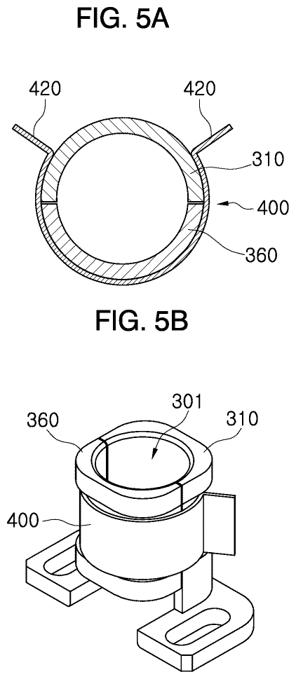

FIG. 4A and 4B are exploded views of an embodiment of the nozzle support member and the coupling member. FIG. 5A is a cross-sectional view of the nozzle support member and the coupling member shown in FIG. 4 and FIG. 5B is a perspective view of the nozzle support member and the coupling member shown in FIG. 4.

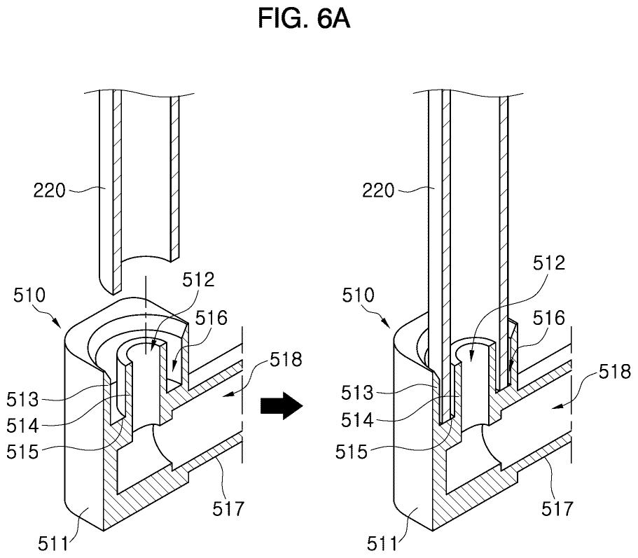

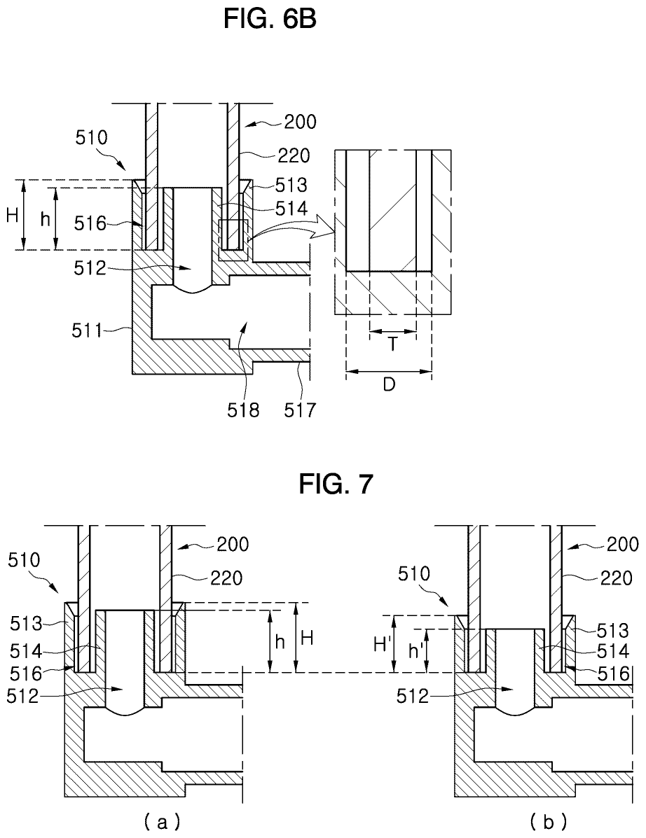

FIG. 6A and 6B are views showing an embodiment in which the gas nozzle is mounted in a supply module body according to the present disclosure.

As an example, the gas nozzle 200 may have one or more injection ports 211 positioned in a nozzle upper end 210.

Furthermore, the gas nozzle 200 may have a nozzle lower end 220 mounted in the upper end of the gas supply module 500.

As an example, the gas nozzle 200 may be formed of a non-metallic material and is preferably formed of quartz.

As an example, the injection port 211 may include one or more through-holes formed in the gas nozzle 200 and oriented toward the process space so as to inject gas into the process space.

The injection port 211 is not limited to the above-described embodiment, and the injection port 211 may be located in the middle end or the lower end of the gas nozzle 200, as necessary. Further, the shape of the injection port 211 may be formed as a branch pipe protruding or extending from the gas nozzle 200.

The mounting part 131 may be formed to protrude from the wall surface of the chamber support 130 toward the center of the chamber support 130.

The mounting part 131 has a groove 134 recessed from the central side surface of the chamber support 130, and the groove 134 in the mounting part 131 is formed to be larger than the outer diameter of the gas nozzle 200 so as to allow the gas nozzle 200 to pass through the internal space in the groove 134.

Furthermore, holes 133 through which bolts or fasteners may pass may be provided in the respective upper ends of both sides of the groove 134 in the mounting part 131.

The nozzle support member 300 may include the first support 310 in contact with one side surface of the gas nozzle 200 and the second support 360 in contact with the other side thereof.

As an example, the first support 310 may be fixedly mounted on the upper surface of the mounting part 131.

As an example, the first support 310 has a flange 321 extending outwards from the lower portion thereof, so that the lower surface of the flange 321 may be mounted on the upper surface of the mounting part 131 protruding from the chamber support 130 in FIG. 3.

That is, the flange 321 of the first support 310 may extend laterally when viewed from the inner center of the chamber support 130 toward the gas supply module insertion hole 132.

The flange 321 of the first support 310 may have a flange slot 322, the major axis of which is oriented toward the center of the internal chamber 110 from the gas supply module insertion hole 132.

The first support 310 may be fixed to the mounting part 131 by inserting a fastener into the slot 322 and the hole 133 formed to correspond to the slot 322 and provided in the mounting part 131.

As an example, the gas nozzle 200 may be mounted in the upper end of one side of the gas supply module 500 in a state in which the nozzle lower end 220 is in close contact with an internal surface 315 of the first support 310.

Furthermore, the gas nozzle 200 may be mounted in the upper end of one side of the gas supply module 500 while the position of the gas supply module 500 is adjusted in a state in which the nozzle lower end 220 is in close contact with the internal surface 315 of the first support 310.

That is, since the first support 310 is used as a vertical arrangement guide and a support for the gas nozzle 200, the gas nozzle 200 may be mounted on the gas supply module 500 in a vertically aligned state, thereby preventing the nozzle lower end 220 from being damaged due to impact or stress.

The position at which the first support 310 contacts the gas nozzle 200 is not limited to the nozzle lower end 220. The position of the first support 310 may be changed depending on the position of the mounting part 131, thereby allowing the first support 310 to contact the upper end or the middle end of the gas nozzle 200, and a guide may be provided so as to mount the gas nozzle 200 in the gas supply module 500 in a vertically aligned state.

Furthermore, a plurality of first supports 310 may be provided. In this case, the first supports 310 may be respectively coupled to a plurality of mounting parts 131 corresponding to the respective supports, and vertical guides may be provided so as to allow the respective first supports 310 to contact the side surfaces of the gas nozzles 200 for vertically arranged insertion of the gas nozzles 200.

As another example, the flange 321 may be additionally disposed on the upper end or the middle end of one first support 310, and the first support 310 may be coupled to a plurality of mounting parts 131 provided on the wall surface of the chamber support 130.

That is, the first support 310 formed to extend in the longitudinal direction thereof may be coupled to the plurality of vertically arranged mounting parts 131, thereby securing vertical stability of the first support 310.

As an example, the coupling member 400 is a C-shaped clip with one side open, and wings may be respectively formed at both ends of the coupling member 400.

That is, the coupling member 400 is made of an elastic material and presses, with elastic force, the nozzle support member 300 located in an internal space 430 in the coupling member 400, thereby allowing the nozzle support member 300 to be in close contact with the gas nozzle 200.

The first support 310 may have an upper step 312 formed on the upper end thereof and configured to fix the coupling member 400 functioning as the C-shaped clip so as to prevent upward movement of the coupling member 400, and a lower step 313 formed on the lower end thereof and configured to fix the coupling member 400 so as to prevent downward movement of the coupling member 400.

The second support 360 may have an upper step 362 formed on the upper end thereof and configured to fix the coupling member 400 functioning as the C-shaped clip so as to prevent upward movement of the coupling member 400, and a lower step 363 formed on the lower end thereof and configured to fix the coupling member 400 so as to prevent downward movement of the coupling member 400.

Furthermore, insertion surfaces 311 and 361 may be respectively formed in the first and second supports 310 and 360. Specifically, the insertion surface 311 is formed between the upper step 312 and the lower step 313 of the first support 310, and the insertion surface 361 is formed between the upper step 362 and the lower step 363 of the second support 360, thereby enabling the first support 310 and the second support 360 to be inserted into the coupling member 400 functioning as the C-shaped clip.

That is, the nozzle support member 300 may be inserted into the internal space 430 in the coupling member 400 so that both ends 314 of the first support 310 respectively contact corresponding both ends 364 of the second support 360, and the internal surface of the coupling member 400 surrounds the insertion surface 361 of the second support 360 from the outside of the second support 360.

The coupling member 400 may elastically press, while surrounding a part of the first support 310, the first support 310 and the second support 360 so as to couple the first support 310 to the second support 360. In this manner, the internal surfaces 315 and 365 respectively formed on the first support 310 and the second support 360 may be in close contact with the external surface of the gas nozzle 200.

When the first support 310 and the second support 360 are in close contact with and are elastically pressed against the side surface of the gas nozzle 200, the gas nozzle 200 may be fixed such that vertical and horizontal movement of the gas nozzle 200 is prevented through friction generated between the side surface of the gas nozzle 200 and the internal surfaces 315 and 365 of the respective supports.

The coupling member 400 has extended wings 420 respectively provided at both ends of the open side thereof. The coupling member 400 may be easily mounted on the nozzle support member 300 by pushing the wings 420 toward the wall surface of the chamber support 130.

In addition, the coupling member 400 may be easily removed from the nozzle support member 300 by pulling the coupling member 400 toward the inner side of the chamber support 130 using the wings 420.

The coupling direction of the coupling member 400 may be changed depending on the shape of the coupling member and the direction in which elastic force of the coupling member is applied, so that the coupling member 400 may be coupled or fixed to the nozzle support member 300 in the other direction.

The gas supply module 500 may be formed of a supply module body 510, a module mounting cover 520, and an adapter 530.

The nozzle lower end 220 of the gas nozzle 200 may be mounted in the upper end of one side of the supply module body 510.

One side of the module mounting cover 520 is inserted into the gas supply module insertion hole 132 from the outside of the chamber support 130.

Furthermore, the other side of the supply module body 510 is inserted, from the inside of the chamber support 130, into one side of the module mounting cover 520 inserted into the gas supply module insertion hole 132.

One side of the adapter 530 is inserted into the other side of the module mounting cover 520.

That is, the other side of the supply module body 510 and one side of the adapter 530 may be in contact with each other inside the module mounting cover 520, and may be fixed by the module mounting cover 520.

A gas supply device (not shown) may be connected to the other side of the adapter 530.

As an example, the supply module body 510 may include a nozzle mounting part 511 formed on one side thereof and configured for the nozzle lower end 220 to be mounted therein, and a horizontal insertion part 517 formed on the other side thereof and inserted into one side of the module mounting cover 520.

As an example, a nozzle mounting groove 516 may be provided in the upper end of the nozzle mounting part 511 such that the nozzle lower end 220 is mounted in the nozzle mounting groove 516, and the nozzle mounting part 511 may have a vertical inlet 512 provided in the upper end thereof and configured for gas to be introduced into the mounted nozzle lower end 220.

The horizontal insertion part 517 located on the side surface of the nozzle mounting part 511 may form a horizontal inlet 518 therein such that gas injected from the adapter 530 is introduced into the nozzle mounting part 511 through the horizontal inlet 518.

The vertical inlet 512 is connected to the horizontal inlet 518 located on the side surface of the nozzle mounting part 511 such that the gas introduced from the horizontal inlet 518 is delivered to the upper end of the vertical inlet 512 and is injected into the nozzle lower end 220.

As another example, the nozzle mounting part 511 and the horizontal insertion part 517 may be separately manufactured as two parts and may be coupled to each other.

As an example, as shown in FIG. 6B, an external wall 513 and an internal wall 514 of the nozzle mounting groove 516 may be formed to be spaced apart from each other so as to have a predetermined distance D therebetween.

Furthermore, the predetermined distance D is configured to be sufficiently larger than a thickness T of the gas nozzle such that the gas nozzle 200 may be mounted in the nozzle mounting groove 516 without damage.

That is, a sufficiently large predetermined distance D may prevent generation of impact and tensile force when the gas nozzle 200 is inserted into the supply module body 510, thereby reducing the risk of damage to the nozzle lower end 220.

Furthermore, a height H of the external wall 513 and a height h of the internal wall 514 of the nozzle mounting groove 516 may be configured such that the gas nozzle 200 is prevented from being separated from the nozzle mounting groove 516.

FIG. 7 is a view showing a modification for adjustment of the height H of the external wall 513 and the height h of the internal wall 514 wall of the nozzle mounting groove.

As an example, the height H of the external wall 513 and the height h of the internal wall 514 in FIG. 7A may be respectively reduced to a height H′ of the external wall 513 and a height h′ of the internal wall 514 in FIG. 7B.

That is, through the reduced heights H′ and h′ of the external wall and the internal wall, it is possible to prevent tensile force from being generated by the external wall 513 and the internal wall 514 of the mounting groove due to inclination of the nozzle lower end 220.

As another example, when the gas nozzle 200 is mounted in an inclined state, the external wall 513 and the internal wall 514 of the mounting groove may be chamfered or filleted at respective upper edges thereof corresponding to the nozzle lower end 220, thereby enabling the nozzle lower end 220 to be mounted in the nozzle mounting groove 516 without damage.

The gas introduced through the gas supply device (not shown) may be injected into the process space through the nozzle injection port 211 via the adapter 530, the horizontal inlet 518, the vertical inlet 512, and the gas nozzle 200 from the outside of the chamber 100.

As another example, the gas supply module 500 may add a sealing member (not shown) between respective members so as to prevent gas leakage between the adapter 530 and the supply module body 510 or between the adapter 530 and a gas supply pipe (not shown).

The configuration and material of the gas supply module 500 may be changed depending on the type, temperature, and pressure of gas to be supplied.

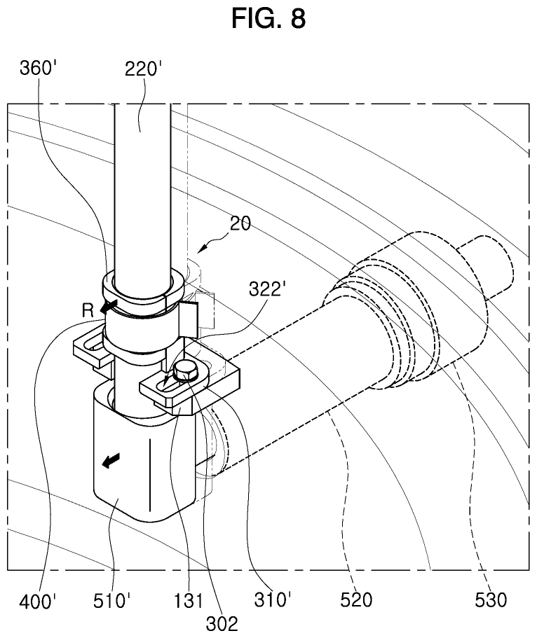

FIG. 8 is a view showing an example of position adjustment of the nozzle assembly 20.

The lower surface of the first support 310 may be mounted on the upper surface of the mounting part 131, and the first support 310 may be fixed in the vertical direction by partially inserting a fastener into the slot 322 and a hole formed to correspond to the slot 322 and provided in the mounting part 131.

The position of the nozzle assembly 20 within the chamber support 130 may be partially adjusted in a R direction toward the inner center of the chamber support 130 from the gas supply module insertion hole 132.

That is, parts 220′, 310′, 360′, 321′, 400′, and 510′ of the nozzle assembly 20 may be adjusted to move in the R direction from the position indicated by two-dot chain lines.

A fastener 302 may be completely inserted into the slot 322 in the first support 310 and the hole 133 in the mounting part, thereby reliably fixing the position of the nozzle assembly 20.

The coupling member 400 is not limited to the clip, and may be modified and implemented, as necessary.

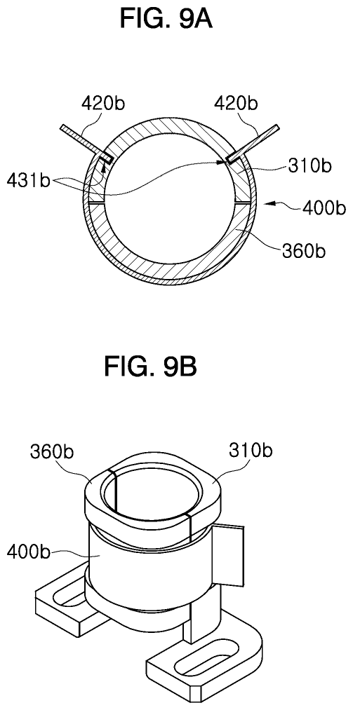

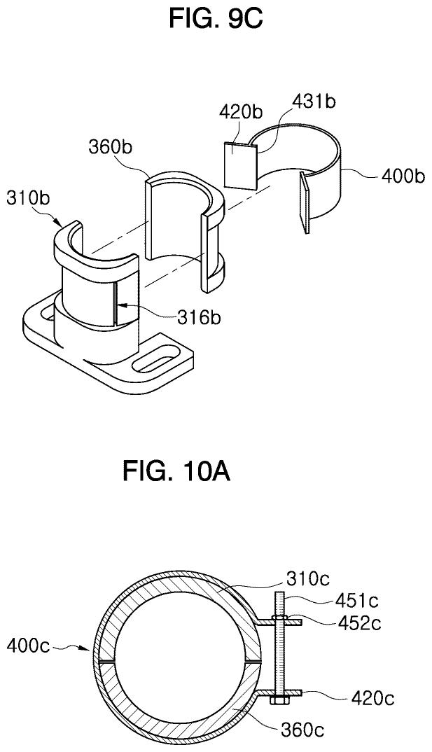

Regarding the coupling member 400, FIGS. 9 to 13 are views each showing an embodiment according to a modification of the nozzle assembly applied to the high-pressure annealing device according to the present disclosure, and a description of a portion overlapping the previously described embodiments will be omitted or briefly described.

As shown in FIGS. 9A, 9B, and 9C, a coupling member 400b has a protrusion 431b formed from a portion at which a wing 420b of a clip starts and oriented in a direction toward the nozzle support member 300. Here, the protrusion 431b is inserted into a groove 316b formed in an insertion portion of a first support 310b such that the coupling member 400b is fixed to the nozzle support member 300.

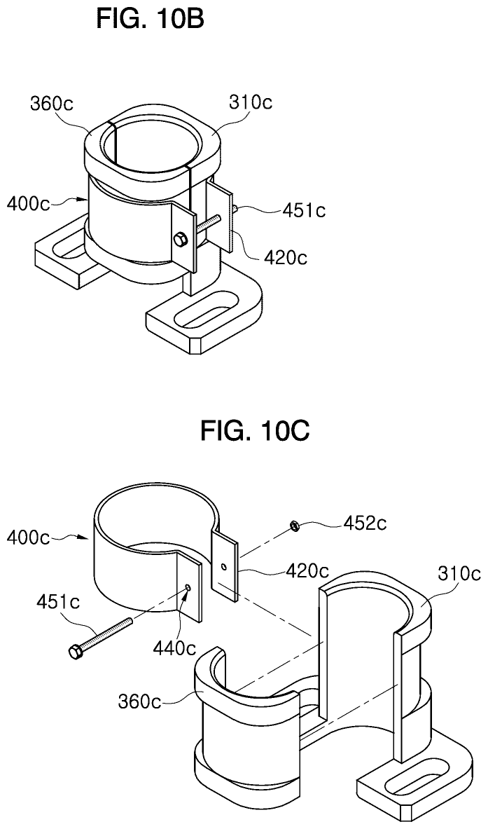

As shown in FIGS. 10A, 10, and 10C, as an example, a coupling member 400c may be formed of a clamp 420c that surrounds insertion surfaces 311c and 361c of a first support 310c and a second support 360c, a bolt 451c for clamp coupling, and a nut 452c.

The coupling member 400c presses the insertion surfaces 311c and 361c of the first support and the second support by inserting the bolt 451c into a hole 440c formed in the clamp 420c. In this manner, the nozzle support member 300 may be in closer contact with the gas nozzle 200 through the coupling member 400c.

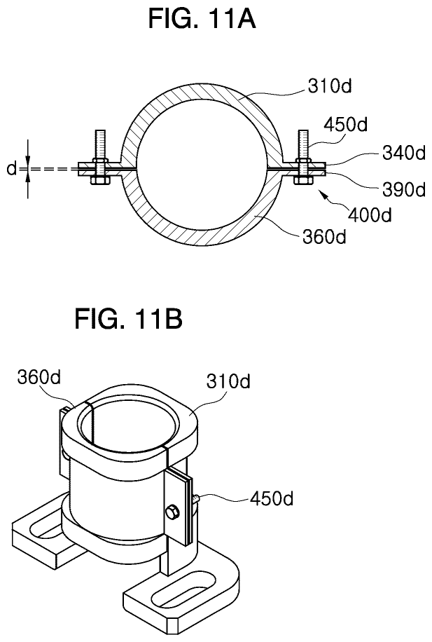

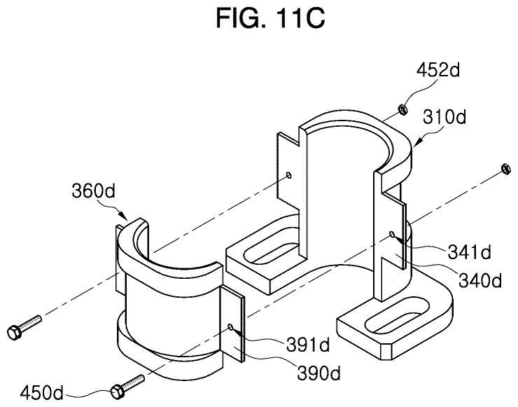

As shown in FIGS. 11A and 11B, as an example, a first support 310d and a second support 360d may respectively have wings 340d and 390d formed to respectively extend from both ends 314 and 364 of the respective supports and oriented in a direction opposite to the internal space 301 of the nozzle support member.

Furthermore, a fastening hole 341d formed in the wing 340d of the first support and a fastening hole 391d formed in the wing 390d of the second support may be formed at positions corresponding to each other.

A fastener 450d and a nut 452d provided in the coupling member 400 may couple the first support 310d to the second support 360d through the fastening hole 391d such that the nozzle support member 300 is in closer contact with the gas nozzle 200.

Furthermore, each of the first support 310d and the second support 360d may be made of an elastic metal, and the wings 340d of the first support and the wings 390d of the second support may be spaced apart from each other by a predetermined distance d.

That is, since the fastener 450d is inserted into the fastening holes 341d and 391d respectively formed in the first support and the second support, the nozzle support member 300 may be in closer contact with the gas nozzle 200 by the fastener 450d.

The configuration for formation of the predetermined distance d between the supports is not limited to the above-described embodiment, and may be applied to other modifications of the coupling member 400 and the nozzle support member 300, as necessary.

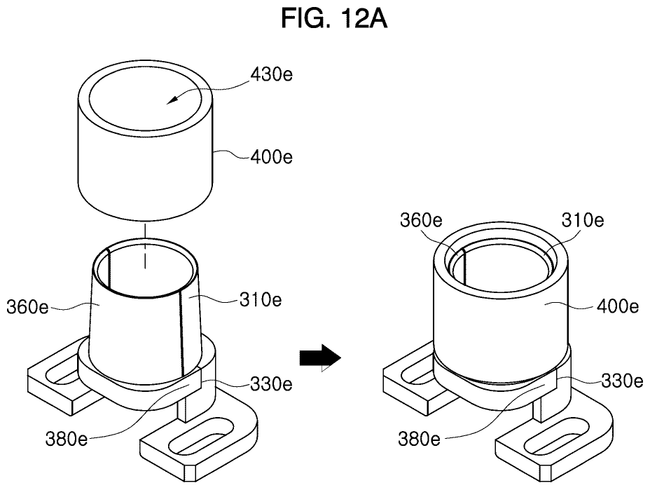

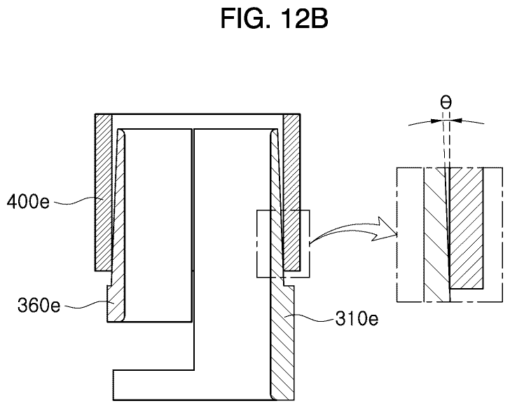

As shown in FIGS. 12A and 12B, as an example, a coupling member 400e is a slider having a through-hole 430e formed therein, and a first support 310e and a second support 360e are provided without formation of the upper steps 312 and 362 so as to be inserted into the through-hole 430e formed in the coupling member 400e.

In addition, the coupling member 400e may contact the insertion surfaces of the first support 310e and the second support 360e to fix the nozzle support member 300 in close contact with the gas nozzle 200.

Furthermore, the second support 360e may include a second support protrusion 380e so as not to be pushed downwards when inserted into the through-hole 430e formed in the coupling member.

That is, the second support protrusion 380e may be formed in such a manner that the lower step 363 of the second support 360e protrudes in a direction toward the lower step 313 of the first support, which corresponds to the lower step 363.

The lower step 313 of the first support 310e may include a first support groove 330e formed to be recessed corresponding to the second support protrusion 380e. In this manner, the second support protrusion 380e of the second support may be inserted into the first support groove 330e.

The first support groove 330e and the second support protrusion 380e are not limited to the above-described embodiment, and may be applied to other modifications of the coupling member 400 and the nozzle support member 300, as necessary. For example, the first support groove 330e and the second support protrusion 380e may be formed at other locations such as both end surfaces of the respective supports other than the lower ends of the respective supports, so that the second support 360 may be fixed so as not to be moved upwards or downwards during coupling between the supports and coupling between the supports and the coupling member.

As an example, each of the first support 310e and the second support 360e may be formed to have a larger thickness at a certain section thereof than a thickness of the upper end thereof. Accordingly, the coupling member 400e may contact the external surface of each of the first and second supports, and the nozzle support member 300 may be in close contact with the gas nozzle 200.

Furthermore, since the thickness of each of the first and second supports is formed to be increased in a direction toward the lower end of each of the first and second supports, pressure applied from the coupling member 400e may be dispersed, thereby reducing the risk of damage to the gas nozzle 200.

That is, the insertion surface of each of the first support 310e and the second support 360e is formed to increase in thickness and forms an inclination angle θ, as shown in FIG. 12B. In this manner, pressure applied from the coupling member 400e to the lower end of the insertion surface is dispersed and transferred to the nozzle lower end 220, thereby reducing the risk of damage to the nozzle lower end 220 and fixing the position of the gas nozzle 200.

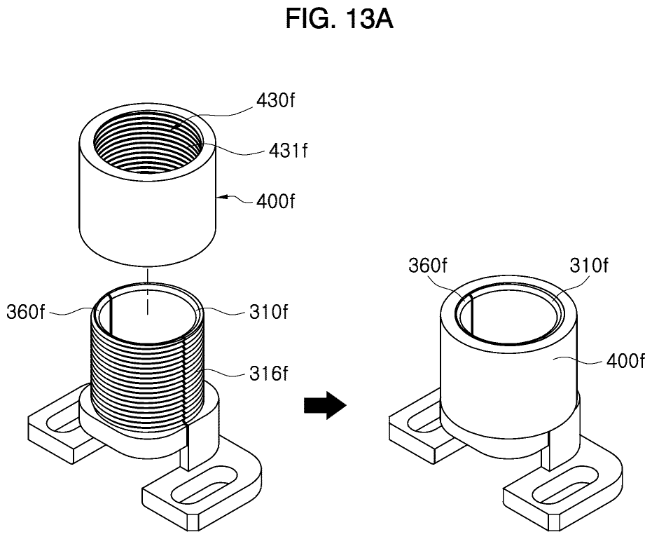

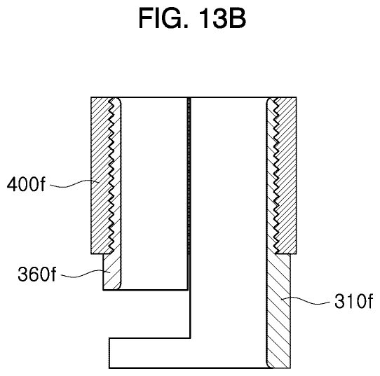

FIGS. 13A and 13B are views showing an example in which a first screw thread 431f is provided on the inside surface of a coupling member 400f, and a second screw thread 316f is provided on the external surface of the nozzle support member 300. Accordingly, the nozzle support member 300 and the gas nozzle 200 may be maintained in a close contact state therebetween when the two screw threads are fastened.

The first screw thread 431f and the second screw thread 316f may be deformed to respectively form a protrusion and a slot. In this case, the coupling member 400f may be coupled to the outside of the first support 310f and the second support 360f in a slot direction in a state in which the protrusion is inserted into the slot.

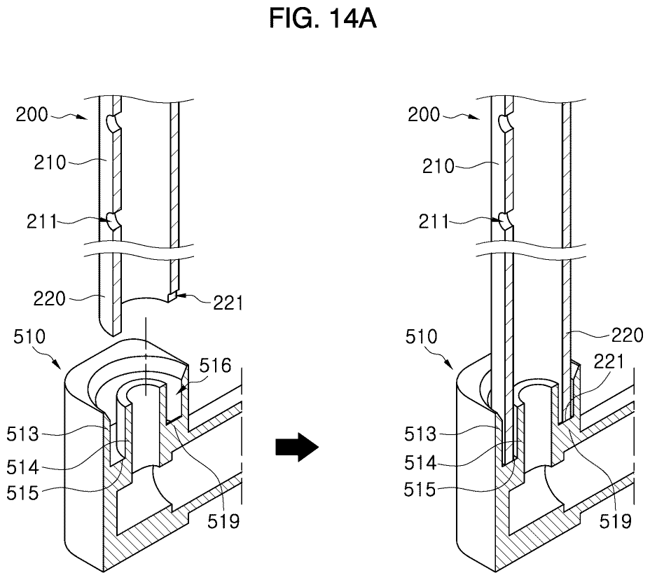

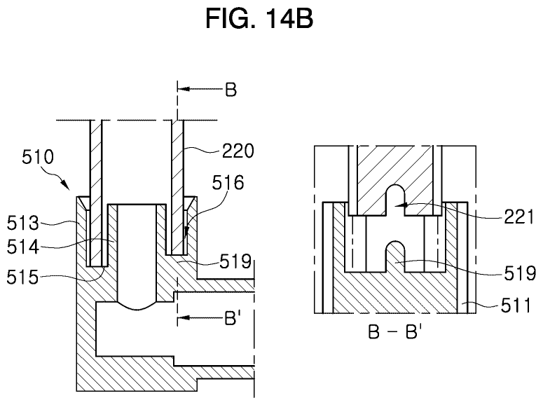

FIGS. 14A and 14B show, as an example, a nozzle alignment groove 221 formed in the nozzle lower end 220 and a nozzle alignment protrusion 519 formed on the supply module body 510.

Regarding the nozzle alignment groove 221 and the nozzle alignment protrusion 519, when the nozzle lower end 220 is coupled to the supply module body 510, the nozzle alignment protrusion 519 may be formed on a certain portion of a mounting surface 515 of the nozzle mounting groove 516, which is in contact with a cross section of the nozzle lower end 220, in order to easily align the direction of the injection port 211, and the nozzle lower end 220 corresponding to the nozzle alignment protrusion 519 may have the nozzle alignment groove 221 provided therein and formed to be recessed upwards.

Therefore, when the nozzle alignment protrusion 519 is aligned with and coupled to the nozzle alignment groove 221, the nozzle injection port 211 may be aligned, and gas injected through the injection port 211 may be supplied toward the upper surface of a substrate located in the process space.

Each of the nozzle alignment groove 221 and the nozzle alignment protrusion 519 may be formed to have an arch shape, as shown in the cross section B-B′, and may be appropriately modified to a different shape, as necessary.

Furthermore, although one nozzle alignment groove 221 and one nozzle alignment protrusion 519 are provided in the embodiment, the present disclosure is not limited thereto. For example, a plurality of the nozzle alignment grooves 221 and a plurality of the nozzle alignment protrusions 519 may be provided to facilitate directional alignment of the gas nozzle 200.

The above-described nozzle assembly is not limited to being applied to a high-pressure annealing chamber formed of a dual chamber. For example, the nozzle assembly may be applied to a high-pressure annealing chamber formed of a single chamber or multiple chambers.

As is apparent from the above description, according to the present disclosure, when a gas nozzle is coupled to a gas supply module, the risk of damage to the gas nozzle may be reduced, vertical and horizontal alignment of the gas nozzle may be secured, and vibration may be reduced during gas supply, thereby having an effect of stably supplying gas.

Particularly, according to the present disclosure, since a nozzle support member is used as a vertical alignment guide, impact generated when the gas nozzle is inserted into the gas supply module is prevented, thereby having an effect of preventing damage to the gas nozzle.

Furthermore, the surface of the nozzle support member is in contact with one side surface of the gas nozzle to support the gas nozzle, thereby vertically aligning the gas nozzle and reducing vibration generated from the nozzle during high-pressure gas supply. Through such a structural configuration, it is possible to prevent generation of particles due to damage to the gas nozzle during a gas supply process.

The effects of the present disclosure are not limited to the above-mentioned effects, and other effects not mentioned herein will be clearly understood by those skilled in the art to which the present disclosure pertains from the detailed description of the embodiments.

Although the embodiments of the present disclosure have been disclosed for illustrative purposes, those skilled in the art will appreciate that various modifications, additions, and substitutions are possible, without departing from the scope and spirit of the disclosure. Therefore, the embodiments described in the present disclosure are not intended to limit the technical idea of the present disclosure, and the technical idea of the present disclosure is not limited by the embodiments. The protection scope of the present disclosure should be interpreted by the following claims, and all technical ideas within the scope equivalent thereto should be construed as being included in the scope of the present disclosure.

What is claimed is:

1. A high-pressure annealing device comprising:
a chamber having a process space provided therein, the process space being configured for gas supplied thereinto and a substrate to react with each other therein;
a nozzle assembly configured to inject the gas into the process space in the chamber; and
a chamber support configured to support the chamber mounted thereon, the chamber support comprising a mounting part formed to protrude from an internal surface thereof, the mounting part being configured for mounting of at least a part of the nozzle assembly thereon,
wherein the nozzle assembly comprises:
a gas supply module configured for a lower end of a gas nozzle to be mounted therein, the gas supply module being configured to supply the gas to the gas nozzle;
the gas nozzle configured to inject the gas into the process space in the chamber;
a nozzle support member comprising a first support and a second support, the first support being configured to surround and contact a part of one side surface of the gas nozzle, the second support facing the first support and being configured to surround and contact a part of the other side surface of the gas nozzle, the nozzle support member being configured to support the gas nozzle mounted in the gas supply module through coupling between the first support and the second support; and
a coupling member configured to couple the first support and the second support to each other.

2. The high-pressure annealing device as claimed in claim 1, wherein the chamber support comprises a gas supply module insertion hole configured for the gas supply module to be inserted thereinto,
wherein the mounting part is located above the gas supply module insertion hole, and
wherein the first support is mounted on an upper end of the mounting part, and a mounting position of the gas nozzle in the gas supply module is adjusted by moving the part of the one side surface of the gas nozzle toward the internal surface for close contact therebetween.

3. The high-pressure annealing device as claimed in claim 2, wherein the first support and the second support surround a part of the gas nozzle in a state in which both ends of the first support and both ends of the second support correspond to each other and contact each other, and
wherein the coupling member contacts and presses external surfaces of the first support and the second support to fix the gas nozzle.

4. The high-pressure annealing device as claimed in claim 2, wherein the first support comprises:
a flange extending outwards from a lower portion of the first support; and
a slot located in the flange, the slot having a major axis oriented toward a center of the chamber support from the gas supply module insertion hole, and
wherein the mounting part comprises a hole formed therein corresponding to the slot and configured for a fastener to pass therethrough, and a mounting position of the nozzle assembly is adjusted by changing a position of the fastener passing through the slot.

5. The high-pressure annealing device as claimed in claim 2, wherein the gas supply module comprises a supply module body comprising a nozzle mounting part and a horizontal insertion part, the nozzle mounting part being formed on one side of the supply module body and being configured for the gas nozzle to be mounted therein, the horizontal insertion part being formed on the other side of the supply module body and being inserted into the gas supply module insertion hole, and
wherein the nozzle mounting part comprises:
a vertical inlet formed in the nozzle mounting part and configured to introduce the gas into the gas nozzle; and
a mounting groove formed in an upper end of the nozzle mounting part and configured for the lower end of the gas nozzle to be mounted therein.

6. The high-pressure annealing device as claimed in claim 1, wherein the coupling member comprises a clip configured to surround an external surface of the first support and an external surface of the second support, the clip being configured to elastically press the respective external surfaces of the first and second supports so as to couple the first support and the second support to each other.

7. The high-pressure annealing device as claimed in claim 1, wherein the coupling member comprises:
a clamp configured to surround an external surface of the first support and an external surface of the second support; and
a bolt coupled to the clamp so as to allow the first support and the second support to be in close contact with the gas nozzle.

8. The high-pressure annealing device as claimed in claim 1, wherein each of the first support and the second support comprises:
extension parts formed to be respectively bent and extend outwards from both ends of each of the first support and the second support; and
fastening holes respectively formed in the extension parts of each of the first support and the second support,
wherein the fastening holes in the first support and the fastening holes in the second support are formed to correspond to each other, and
wherein the coupling member comprises fasteners configured to pass through the respective fastening holes so as to couple the first support to the second support such that the first support and the second support are in close contact with the gas nozzle.

9. The high-pressure annealing device as claimed in claim 1, wherein the coupling member comprises a slider having a through-hole formed therein and configured for the first support and the second support in contact with each other to be inserted thereinto, and
wherein the slider contacts external surfaces of the first support and the second support inserted into the through-hole such that the first support and the second support are in close contact with the gas nozzle.

10. The high-pressure annealing device as claimed in claim 9, wherein each of the first support and the second support has a first screw thread formed on the external surface thereof, and the slider has a second screw thread formed on an internal surface thereof, and
wherein the first screw thread and the second screw thread are fastened.

11. The high-pressure annealing device as claimed in claim 5, wherein the mounting groove comprises a nozzle alignment protrusion formed to protrude upwards from a part of the mounting groove,
wherein the gas nozzle comprises a nozzle alignment groove formed to be recessed inwards at a position corresponding to the nozzle alignment protrusion, and
wherein the nozzle alignment protrusion is aligned with and coupled to the nozzle alignment groove so as to align a direction of an injection port of the gas nozzle.
